(19) United States
(12) Patent Application Publication
(10) Pub. No.: US 2010/0109080 A1
(43) Pub. Date: May 6, 2010

(54) PSEUDO-DRAIN MOS TRANSISTOR

(76) Inventors: Sheng-Yi Huang, Hsinchu County (TW); Cheng-Chou Hung, Hsinchu County (TW); Tzung-Lin Li, Pingtung County (TW); Chin-Lan Tseng, Miaoli County (TW); Victor-Chiang Liang, Hsin-Chu City (TW); Chih-Yu Tseng, Hsinchu City (TW)

Correspondence Address: NORTH AMERICA INTELLECTUAL PROPERTY CORPORATION, P.O. BOX 506, MERRIFIELD, VA, 22116, US

(21) Appl. No.: 12/264,912

(22) Filed: Nov. 5, 2008

(51) Int. Cl. H01L 29/78

(52) U.S. Cl. 257/335; 257/E29.256

(57) ABSTRACT

A pseudo-drain MOS transistor is disclosed. The transistor includes a semiconductor substrate; a gate structure disposed on the semiconductor substrate; a source, a pseudo-drain, a drain, and a shallow trench isolation disposed in the semiconductor substrate, a p-well disposed in the semiconductor substrate and under the source and the gate structure; and an n-well disposed under the drain. The source and the pseudo-drain are disposed adjacent to two sides of the gate structure and the shallow trench isolation is disposed between the pseudo-drain and the drain, and the n-well is extended toward the pseudo-drain while not reaching the area below the gate structure.

### BACKGROUND OF THE INVENTION

1. Field of the Invention

The invention relates to a MOS transistor, and more particularly, to a pseudo-drain MOS transistor.

2. Description of the Prior Art

Current power systems provide an alternating current having a variety of frequencies ranging from 50 to 60 Hz, and a voltage ranging from 100 to 240 volts (V). Every electrical device has a particular working voltage and frequency condition, and therefore, electrical devices and related passive elements utilized in the electrical devices, such as inductors, capacitors, resistors and transformers, act as a switch to determine the value of the voltage and the type of the current thereof. For example, a conventional air conditioner utilizes a power supply providing a low-voltage current for the inner facilities. The power supply switch reduces the voltage provided by the outer power system to an appropriate voltage for the inner facilities. In addition, the power supply switch has the characteristics of high efficiency, low weight, small size and reduced power consumption.

High-voltage metal-oxide semiconductor (HV MOS) transistor devices may function as switches and are broadly utilized in CPU power supplies, power management systems, AC/DC converters, LCD/plasma TV drivers, automobile electronic components, PC peripheral devices, small DC motor controllers, and other consumer electronic devices.

HV MOS transistors used today are typically fabricated in the form of lateral diffusion transistors and drain-extended transistors. These transistors commonly have thicker gate insulating layer thereby having higher threshold for high voltages. Referring to FIG. 1, FIG. 1 illustrates a structural view of a drain-extended MOS transistor according to the prior art. As shown in FIG. 1, the conventional HV n-type MOS transistor includes a semiconductor substrate 12, an n-well 14 and a p-well 16 disposed in the semiconductor substrate 12, a gate structure 18 disposed in the semiconductor substrate 12 while overlapping both the n-well 14 and the p-well 16, a lightly doped drain 104 and a source 20 disposed in the p-well 16, a drain 22 disposed in the n-well 14, and a plurality of shallow trench isolations 24 disposed in the semiconductor substrate 12. The gate structure 18 includes a gate electrode 26 and a gate insulating layer 28 disposed between the gate electrode 26 and the semiconductor substrate 12. A spacer 30 is disposed on the sidewall of the gate structure 18, and a silicide layer 32 is disposed on top of the gate structure 18 and the surface of the source 20 and drain 22.

It should be noted that the n-well 14 of the transistor is formed to enclose the entire shallow trench isolation 24 while extending to the region below the gate structure 18 to occupy a major portion of the channel region, such that only a small portion of the channel region under the gate electrode 26 is covered by the p-well 16. As electrons are only controlled by an inversion layer created between the gate electrode 26 and the p-well 16 while passing through the channel region, the presence of the n-well 14 limits the area of the inversion layer and causes only a small portion of the channel region to be controlled by the gate, thereby affecting the transport of the electrons and on-off speed of the transistor.

As the majority of high radio-frequency applications used today, such as power amplifiers require a much higher frequency feedback and faster on-off speed, the aforementioned drain-extended MOS transistor having poor gate control ability clearly cannot be utilized for fabricating advanced product in high radio-frequency field. Hence, how to improve the current fabrication for producing desirable transistors for high radio-frequency applications has become a critical task.

### SUMMARY OF THE INVENTION

It is an objective of the present invention to provide a pseudo-drain MOS transistor for improving the current design of drain-extended MOS transistors having insufficient on-off speed.

According to a preferred embodiment of the present invention, a pseudo-drain MOS transistor is disclosed. The pseudo-drain MOS transistor preferably includes: a semiconductor substrate; a gate structure disposed on the semiconductor substrate; a source, a pseudo-drain, a drain, and a shallow trench isolation disposed in the semiconductor substrate, wherein the shallow trench isolation is disposed between the pseudo-drain and the drain; a p-well disposed in the semiconductor substrate and under the drain and the gate structure; and a n-well disposed under the shallow trench isolation and the drain, wherein the n-well extends toward the pseudo-drain while not reaching the area below the gate structure.

Another aspect of the present invention provides a pseudo-drain MOS transistor having: a semiconductor substrate, a first transistor disposed on the semiconductor substrate, a second transistor disposed on the semiconductor substrate, a drain disposed between the first transistor and the second transistor; a first shallow trench isolation disposed between the first transistor and the drain; and a second shallow trench isolation disposed between the second transistor and the drain. The first transistor includes a first gate structure disposed on the semiconductor substrate and a first source and a first pseudo-drain disposed in the semiconductor substrate adjacent to two sides of the first gate structure. The second transistor includes a second gate structure disposed on the semiconductor substrate and a second source and a second pseudo-drain disposed in the semiconductor substrate adjacent to two sides of the second gate structure.

Specifically, the transistor of the present invention includes a pseudo-drain disposed between the gate structure of the transistor and the shallow trench isolation, and the n-well of the transistor is formed to extend from the area below the drain to the edge of the gate structure. As the n-well does not reach the area below the gate structure and the channel region under the gate structure is completely covered by p-well, the area of the inversion layer in the channel region is increased significantly thereby enabling the electrons passing through the channel region to be completely controlled by the gate and inhibiting any drifting of electrons in the channel region. As a result, the response rate and breakdown voltage of the transistor is increased and the performance of the device is improved.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a structural view of a drain-extended MOS transistor according to the prior art.

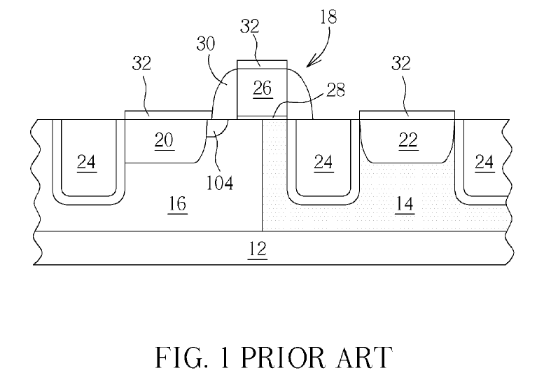

FIG. 2 illustrates a method for fabricating a pseudo-drain MOS transistor according to a preferred embodiment of the present invention.

FIG. 3 illustrates a method for fabricating a pseudo-drain MOS transistor according to an embodiment of the present invention.

### DETAILED DESCRIPTION

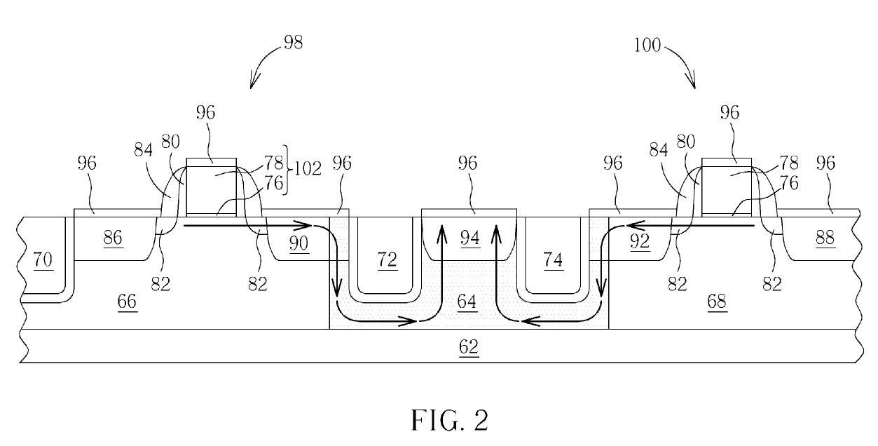

Referring to FIG. 2, FIG. 2 illustrates a method for fabricating a pseudo-drain MOS transistor according to a preferred embodiment of the present invention. As shown in FIG. 2, a semiconductor substrate 62, such as a silicon wafer or silicon-on-insulator substrate is provided. A plurality of ion implantations and shallow trench isolation formations are conducted to form a plurality of first conductive type wells, at least one second conductive type well, and a plurality of shallow trench isolations 70, 72, 74. Preferably, the first conductive type wells are p-type wells 66, 68 and the second conductive type well is n-type well 64. Alternatively, the first conductive type wells could also be n-type wells and the second conductive type well could be p-type well, which is also within the scope of the present invention. A MOS transistor having an n-well 64 surrounding by two p-wells 66, 68 is disclosed in this embodiment. However, a plurality of n-wells and p-wells could further be added around the p-wells 66, 68 according to the demand of the product, which are all within the scope of the present invention.

A gate structure is then formed on the p-wells 66, 68. For instance, a gate insulating layer (not shown) composed of silicon oxide or silicon nitride could be disposed on the surface of the p-wells 66, 68. Preferably, the thickness of the gate insulating layer could be adjusted according to the demand of the product. For instance, if the transistor is applied to a radio-frequency chip, the gate insulating layer is preferably fabricated with a thickness less than 50 angstroms, whereas if the transistor is applied to an I/O device, the deposited gate insulating layer would have a thickness of several hundreds angstroms.

An n-type ion implantation may be conducted to form a doped or undoped polysilicon layer (not shown) on the gate insulating layer, and a photo-etching process is conducted on the polysilicon layer and the gate insulating layer. For instance, a patterned photoresist (not shown) could be formed on the surface of the polysilicon layer, and an etching process is performed by using the patterned photoresist as mask to remove a portion of the polysilicon layer and the gate insulating layer, thereby forming a plurality of gate electrodes composed of patterned polysilicon layer and a plurality of patterned gate insulating layer 76. After the photoresist is removed, a gate structure 102 composed of the gate electrode 76 and gate insulating layer 78 is formed on each p-well 66, 68.

Next, an offset spacer formation is conducted after the n-type gate electrode 78 is formed. For instance, a silicon oxide layer or a silicon nitride layer could be deposited and etched back on the sidewall of each n-type gate electrode 78 to form an offset spacer 80. A lightly doped ion implantation is then conducted by using the gate electrode 78 and the offset spacer 80 as mask to form an n-type lightly doped drain 82 in the semiconductor substrate 62 adjacent to two sides of the offset spacer 80. A main spacer formation is conducted by depositing and etching back a silicon nitride layer or silicon oxide layer around the offset spacer 80 to form a main spacer 84.

An n-type heavy doped ion implantation is conducted by using the gate electrode 78 and the main spacer 84 as mask to form two sources 86, 88 and two pseudo-drains 90, 92 in the p-wells 66, 68 adjacent to two sides of the main spacer 84, and at the same time form a drain 94 in the n-well 64 between the two shallow trench isolations 72, 74.

It should be noted in addition to the order for forming the offset spacer 80, the lightly doped drains 82, the main spacer 84, and the sources 86, 88, the pseudo-drains 90, 92, and the drain 94, the number of the spacers and the order for forming these doping regions and spacers could also be adjusted according to the demand of the product, which are all within the scope of the present invention.

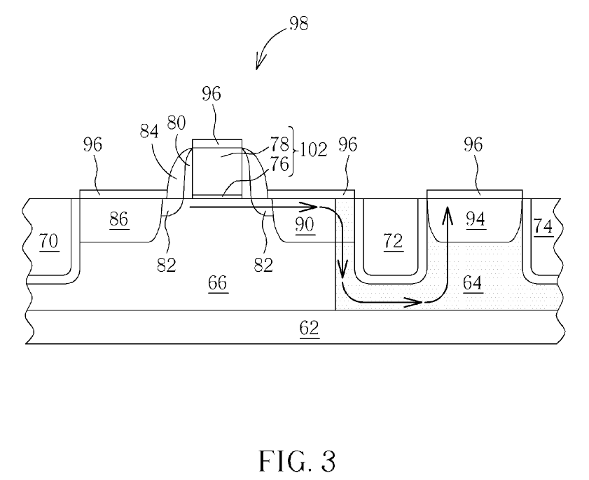

After the sources 86, 88, the pseudo-drains 90, 92, and the drain 94 are formed, a salicide process is performed by first depositing a metal layer (not shown) composed of cobalt, titanium, nickel, platinum, palladium, or molybdenum over the surface of the substrate 62, and a rapid thermal annealing process is conducted to form a silicide 96 on top of the gate electrodes 78 and at two sides of the spacers 84. Un-reacted metal layer remained from the salicide process is removed thereafter. It should also be noted that in addition to the parallel design of utilizing two transistors 98, 100 to surround a drain 94, the present invention could also dispose only one transistor 98 having a source 86 and pseudo-drain 90 adjacent to the drain 94, as shown in FIG. 3, which is also within the scope of the present invention.

Referring again to FIG. 2, the MOS transistor disclosed preferably includes a semiconductor substrate 62, two first conductive type wells such as p-wells 66, 68 disposed in the semiconductor substrate 62, a second conductive type well such as n-well 64 disposed between the p-wells 66, 68, a plurality of shallow trench isolations 70, 72, 74 formed for separating the p-wells 66, 68 and the n-well 64, two transistors 98, 100 disposed on the p-wells 66, 68 respectively, and a drain 94 disposed in the n-well 64 between the two transistors 98, 100. Each of the transistors 98, 100 includes a gate structure 102, a plurality of spacers 80, 84 disposed on the sidewall of the gate structure 102, and a source 86/88 and a pseudo-drain 90/92 disposed in the semiconductor substrate 62 adjacent to two sides of the gate structure 102. According to a preferred embodiment of the present invention, the first conductive type wells are p-wells 66, 68, the second conductive type well is an n-well 64, and the transistors 98, 100 are NMOS transistors. The NMOS transistors 98, 100 are disposed on the p-wells 66, 68 respectively, and an n-well 64 is sandwiched between the two p-wells 66, 68. Alternatively, the first conductive type wells could also be n-wells, the second conductive type well could be p-well, and the two transistors 98, 100 could be PMOS transistors that are disposed on two n-wells sandwiching a p-well. The resulting structure would preferably be opposite to the structure shown in FIG. 2, and this design is also within the scope of the present invention.

According to a preferred embodiment of the present invention, two pseudo-drains 90, 92 are disposed between the gate structures 102 of the transistors 98, 100 and the shallow trench isolations 72, 74, and the n-well 64 is formed to extend from the area below the drain 94 toward the pseudo-drains 90, 92 of the two transistors 98, 100 until reaching the edge of the gate structure 102. In other words, the n-well 64 does not extend to the area below the gate structure 102, such that the electrons would travel from the sources 86, 88 through the inversion layer in the channel region and then drift (such as the direction pointed by the arrow) along the pseudo-drains 90, 92 and the sidewall of the shallow trench isolations 72, 74 to the drain 94.

As the n-well 64 does not extend to the area below the gate structure 102 and the channel region under the gate structure 102 is completely covered by the p-wells 66, 68, the inversion layer in the channel region is increased significantly to enable the electrons passing through the channel region to be completely controlled by the gate without causing a drift of electrons in the channel region. Moreover, as the entire channel region is controlled by the gate, the response rate and the on-off speed of the gate is improved and the breakdown voltage of the device is also increased, thereby improving the overall performance of the device while utilized in the high radio-frequency product.

Those skilled in the art will readily observe that numerous modifications and alterations of the device and method may be made while retaining the teachings of the invention.

What is claimed is:

1. A pseudo-drain MOS transistor, comprising:
a semiconductor substrate;
a gate structure disposed on the semiconductor substrate;
a source, a pseudo-drain, a drain, and a shallow trench isolation disposed in the semiconductor substrate, wherein the source and the pseudo-drain are disposed adjacent to two sides of the gate structure and the shallow trench isolation is disposed between the pseudo-drain and the drain;
a first conductive type well disposed in the semiconductor substrate and under the drain and the gate structure; and
a second conductive type well disposed under the shallow trench isolation and the drain, wherein the second conductive type well extends toward the pseudo-drain while not reaching the area below the gate structure.

2. The pseudo-drain MOS transistor of claim 1, wherein the gate structure comprises a gate electrode and a gate insulating layer disposed between the gate electrode and the semiconductor substrate.

3. The pseudo-drain MOS transistor of claim 2, wherein the gate insulating layer comprises a thickness less than 50 angstroms.

4. The pseudo-drain MOS transistor of claim 1, further comprising a spacer disposed on the sidewall of the gate structure.

5. A pseudo-drain MOS transistor, comprising:
a semiconductor substrate;
a first transistor disposed on the semiconductor substrate, comprising:
a first gate structure disposed on the semiconductor substrate; and
a first source and a first pseudo-drain disposed in the semiconductor substrate adjacent to two sides of the first gate structure;
a second transistor disposed on the semiconductor substrate, comprising:
a second gate structure disposed on the semiconductor substrate; and
a second source and a second pseudo-drain disposed in the semiconductor substrate adjacent to two sides of the second gate structure;
a drain disposed between the first transistor and the second transistor;
a first shallow trench isolation disposed between the first transistor and the drain; and
a second shallow trench isolation disposed between the second transistor and the drain.

6. The pseudo-drain MOS transistor of claim 5, wherein two ends of the drain are extended to the sidewall of the first shallow trench isolation and the second shallow trench isolation.

7. The pseudo-drain MOS transistor of claim 5, further comprising a first conductive type well disposed below the first gate structure, the first source, and the first pseudo-drain.

8. The pseudo-drain MOS transistor of claim 5, further comprising a first conductive type well disposed below the second gate structure, the second source, and the second pseudo-drain.

9. The pseudo-drain MOS transistor of claim 5, further comprising a second conductive type well disposed below the drain while not reaching the area below the first gate structure of the first transistor and the second gate structure of the second transistor.

10. The pseudo-drain MOS transistor of claim 5, wherein the first gate structure comprises a first gate electrode and a first gate insulating layer disposed between the first gate electrode and the semiconductor substrate.

11. The pseudo-drain MOS transistor of claim 5, further comprising a first spacer disposed on the sidewall of the first gate structure.

12. The pseudo-drain MOS transistor of claim 5, wherein the second gate structure comprises a second gate electrode and a second gate insulating layer disposed between the second gate electrode and the semiconductor substrate.

13. The pseudo-drain MOS transistor of claim 5, further comprising a second spacer disposed on the sidewall of the second gate structure.

14. The pseudo-drain MOS transistor of claim 5, wherein the first shallow trench isolation is disposed between the first pseudo-drain and the drain.

15. The pseudo-drain MOS transistor of claim 5, wherein the second shallow trench isolation is disposed between the second pseudo-drain and the drain.
